(19) United States
(12) Patent Application Publication
(10) Pub. No.: US 2025/0070779 A1
(43) Pub. Date: Feb. 27, 2025

(54) CIRCUITS AND METHODS TO USE ENERGY HARVESTED FROM TRANSIENT ON-CHIP DATA

(71) Applicant: Metis Microsystems, LLC, Newtown, CT (US)

(72) Inventor: Azeez BHAVNAGARWALA, Newtown, CT (US)

(73) Assignee: Metis Microsystems, LLC, Newtown, CT (US)

(21) Appl. No.: 18/624,649

(22) Filed: Apr. 2, 2024

Related U.S. Application Data
(63) Continuation of application No. 17/497,974, filed on Oct. 10, 2021, now Pat. No. 11,984,887.
(60) Provisional application No. 63/139,744, filed on Jan. 20, 2021.
(60) Provisional application No. 63/090,169, filed on Oct. 9, 2020.

(51) Int. Cl. H03K 19/00; G01R 19/165; H03K 19/094; H03K 19/096; H03K 19/20

(52) U.S. Cl. CPC H03K 19/0019; G01R 19/16552; H03K 19/0013; H03K 19/094; H03K 19/0963; H03K 19/20

(57) ABSTRACT

Circuits and methods that use harvested electrostatic energy from transient: on-chip data are described in the Application. In one aspect, a method inverter circuit use harvested electrostatic charge held at any electric potential higher than the common ground reference potential of CMOS circuits in a chip, to partially drive a 0→1 logic transition at the output of the inverter at lower energy drain from the on-chip power grid than a conventional CMOS inverter with similar performance, slew rates at inverter input and output and with similar output driving transistor geometries.

### CROSS-REFERENCE TO RELATED APPLICATIONS

This application is a Continuation of U.S. patent application Ser. No. 17/497,974, filed Oct. 10, 2021, which claims priority to and benefit of U.S. Provisional Application No. 63/090,169 filed on Oct. 9, 2020, and U.S. Provisional Application No. 63/139,744 filed on Jan. 20, 2021, the entire disclosures of each of which are incorporated herein by reference in its entirety.

### FIELD OF INVENTION

The present invention relates to use of electrostatic energy harvested from transient on-chip data to improve the energy efficiency of digital CMOS circuit operation.

### BACKGROUND OF INVENTION

In recent years, deep neural networks (DNNs) have become the solution for many AI applications including computer vision, speech recognition and robotics implementing machine learning methods. While these neural networks deliver sufficient accuracy—it comes at the cost of high computational complexity with associated power drain limiting deep learning from being deployed on mobile devices with limited energy budgets. Smart phones for example, cannot run object classification with AleXNet in real-time for more than an hour. Network issues of latency, bandwidth and availability could require battery/ambient powered IoT devices on the edge to not only sense and act without communicating to the cloud but also to take on more computationally intense tasks of learning or training a neural network. Neural networks for a myriad of IoT devices can easily result in model sizes that are enormous-becoming computationally burdensome to their energy resources, demanding energy budgets that exceed provisions from batteries and conventional energy harvesting methods. Even where power is abundantly available as in a data center supporting AI workloads, where GPU accelerators consume as much as 400 W, the cost of electricity and the performance limits imposed by heat removal efficiency can be improved by lowering the switching (or Dynamic) energy consumption of digital CMOS circuits.

### PRIOR ART

In many applications requiring high speed CMOS circuit operation, precharged dynamic circuit techniques are preferred. These circuits are typically operated by pre-charging output nodes to the supply voltage during a pre-charge phase every clock cycle and conditionally discharging some of them, depending on the inputs during the evaluation phase. These techniques are energy inefficient since all of the charge discarded to the reference ground potential during evaluate must be resupplied during the precharge phase of the next clock cycle. High peak currents can also cause large di/dt noise causing voltage bumps in power rails associated risks to signal integrity and reliability in high performance CMOS components.

Dynamic logic circuits that recycle some of the charge were proposed to improve the energy efficiency of circuit operation. These circuit techniques precharge complementary outputs to half V_{DD} by charge sharing from the previous evaluation state, enabling a maximum of a 50% reduction in energy. Such schemes are relevant only when complementary signal pairs are used in implementing complex logic functions. Also, much of the charge recycle benefits are lost with performance degraded as well due to (i) high overheads in device count (ii) requirement of using complementary inputs and as many as 2-3 clock and enable inputs to each logic gate with their associated additional routing, performance and power overheads (iii) use of cross-coupled inverters as output drivers which increase the uncertainty of gate metrics in the presence of parameter variations and the offsets they develop, and (iv) with only a half-VDD gate-source voltage precharged to output and input nodes of output drivers for charge recycle operation, gate overdrive is degraded during evaluation phase. In one comparison with static CMOS implementing full adders, the power-delay product of a full adder increases total energy nearly 10% over static CMOS. Moreover, neural network energy consumption is dominated by movement of data across the memory hierarchy and the chip and not by dissipation from computation.

On-chip small voltage swing signaling. schemes have attempted charge recycling by stacking components (such as logic and clocking circuits) with predictable data switching activities in two adjacent voltage domains using simple push-pull regulators to balance current between the two domains to maintain the voltage at their interface. This approach could deliver a maximum of a quadratic reduction in power. Inefficiency introduced by voltage regulation is eliminated if the current between domains is matched. An approach to stack voltage domains without requiring regulators between them has been reported using a balanced charge recycling bus where differing data activity between two links is compensated by swapping data between them periodically so that switching activity along the bus is exactly matched. These schemes however, are difficult to implement and also require circuits in the domains to be powered by reduced operating voltages.

Charge recycling techniques have been reported where the flow of electric charge from the supply rail (V_{DD}) to Ground is traced through more than one circuit/use through multiple voltage domains. However, there is no energy advantage from recycling the charge through multiple voltage domains since it costs as much in energy to raise share 0 the highest voltage domain as it does to de so cumulatively in each of the. stacked domains operating independently. The energy advantage of stacking voltage domains is only in removing the inefficiencies of on-chip voltage regulation from (V_{DD}) to much lower voltages that these domains would be powered with to benefit from quadratic reductions in their switching power. If the current between domains is not matched, the energy overhead consumed by regulators attempting to maintain domain interface at a fixed voltage, could diminish the quadratic energy improvements from operating each domain at reduced voltages.

Non-resonant approaches to returning/recycling stored on load capacitance include use of an inductor to discharge load capacitor of a clock network to the power grid instead of it being discharged to ground. However, overheads of inductors, decoupling capacitors, integration with clock gating (and its accompanying overheads), and limited application to large clock load capacitances (as seen in a clock mesh) are challenges seen with this approach making it impractical and difficult to implement.

Smaller voltage transitions for each logic, operation using ‘recycled charge’ also with the disadvantages of smaller margins and lower performance. In multiple instances, these make implementations impractical. For e.g., a smaller (than V_{DD}) voltage is applied across a BL pair during an SRAM Write operation to enable lower energy dissipation per Write Operation. By sharing/recycling charge across a set of BL pairs, Writes are attempted with smaller voltage swings on the BL (instead Of full rail-rail BL swings during a conventional SRAM Write). For small geometry devices it becomes harder to write to the bitcell even with the full supply voltage across a bit line pair-due to increasing electrical variability seen in small-geometry bitcell transistors. Circuit overheads introduced by full CMOS transmission gates to move charge between columns comes at a significant cost in area, control and performance.

Adiabatic switching in reversible logic circuits moves charge from the power supply to a load capacitance using slow constant current charging without energy dissipation. It enables the recycling of energy to reduce the total energy drawn from the power supply by reversing the current source using non-standard AC or pulsed power supplies with time varying voltage or current. In sharp contrast to conventional CMOS circuit operation, charge and energy are not discarded after being used only once—with pulsed/sinusoidal cower supplies designed to be able. to retrieve the energy fed back to it. The problem areas limiting realization of practical low-power operation of CMOS chips using adiabatic or reversible logic techniques; (1) the energy-efficient design of the combined power supply and clock generator (2) logical overhead needed to support reversible logic functions and (3) the alternative of scaling operating voltages with feature size and improving performance—that comes with conceptual simplicity and high payback of lower power dissipation, has: been preferred by industry.

### SUMMARY OF INVENTION

Conventional CMOS operation as illustrated by an inverter driving a capacitive load C and which draws energy equal to CV_{DD}² from the power supply rail at voltage V_{DD} during a 0→1 transition at its output, of which energy equal to (½) CV_{DD}² is stored at the output. A 1→0 transition at the output discharges all of this stored energy to the reference ground potential of the inverter at voltage Vss=0V.

In the proposed invention, an inverter driving the same capacitive load C as the above conventional CMOS inverter, draws energy equal to αCV_{DD}² (where a is a positive fraction<1) from a grid/node capacitance holding harvested electrostatic charge at some intermediate electric potential V2 where V2≥Vss and V2≤Vss as the inverter uses this harvested charge to drive a 0→1 transition at its output, until the output voltage approaches V2 when the proposed circuit invention continues driving the output to V_{DD} using electric charge from the power grid of the chip at electric potential V_{DD} while consuming energy equal to only βCB_{DD}² where β is a positive fraction<1) with a α+β˜1. Typical values of β are 0.6-0.75.

### BRIEF DESCRIPTION OF DRAWINGS

FIG. 1 is a schematic illustrating conventional CMOS circuit schematic of an inverter and its operation in response to 1→0 and 0→1 input transitions

FIG. 2 is a circuit simulation: of the conventional CMOS inverter circuit that shows voltage waveforms at the input and at the output terminals of the inverter in response to 1→0 and 0→1 input transitions. The Figure also shows the current waveform that illustrates the current flow dependence on time for the 0→1 transition at the output and the 1→0 transition at the output.

FIG. 3 is a schematic illustrating the proposed circuit Of an inverter that uses harvested charge held at a grid/node capacitance at any voltage (between the power rails at the supply voltage and the reference ground potential) to drive its output during a 0→1 voltage transition at an energy Cost of 0.6×-0.75× of that seen in a conventional CMOS inverter

FIG. 4 is a circuit simulation of the proposed inverter circuit that uses harvested charge to power the 0→1 voltage transition at its output-showing voltage waveforms at the input and output terminals (that are practically identical to those observed in a conventional CMOS inverter (FIG. 2)) and current waveforms corresponding to current drawn from the grid holding harvested 6harge at VDD/2 and the current drawn from the power rail at voltage=VDD.

### DETAILED DESCRIPTION OF PREFERRED EMBODIMENTS

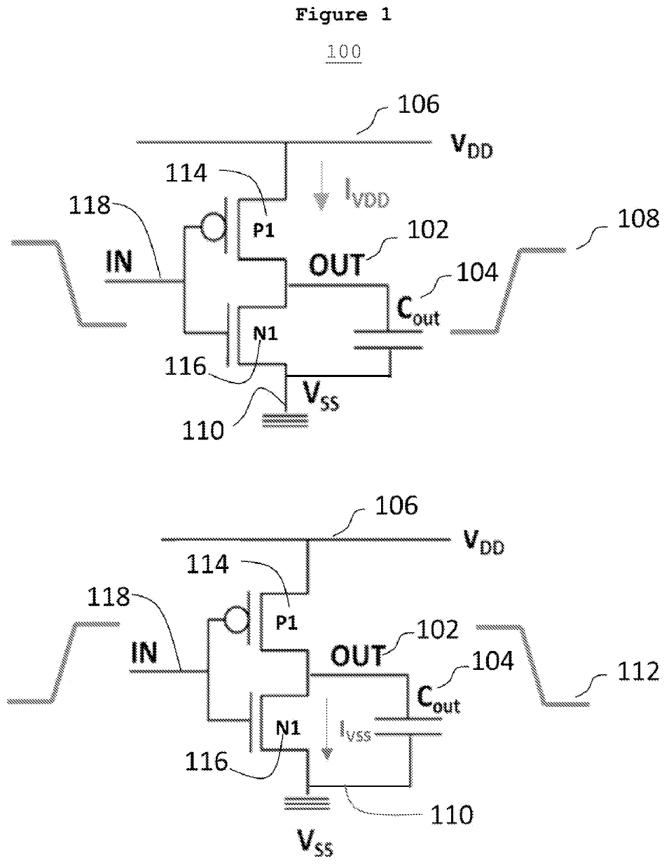

FIG. 1 is a schematic illustrating operation of a conventional CMQS inverter 100 driving output node OUT 102 with a capacitive load Cₒᵤₜ 104. The power rail 106 at electric potential V_{DD} provides total energy equal to Cₒᵤₜ V_{DD}² (derived in equation (1) below) during a 0→1 transition 108 at the output node OUT 102, storing energy of (½)CₒᵤₜV_{DD}² on the capacitor 104 at the output 102 modeled by equation (2) below. A 1→0 112 transition at the output 102 discharges from Cₒᵤₜ 104 all of this stored energy on the capacitor Cₒᵤₜ 104 at the output 102 to the reference ground node 110 at electric potential Vss=0V

Energy Drawn from VDD Supply (During 0→1 Transition at Output)

$$\int \text{?} = \text{?} = \text{?} \qquad ( 1 )$$

$$\text{?} \text{indicates text missing or illegible when filed}$$

### Energy Stored at Output

$$\int \text{?} = \text{?} = \text{?} \qquad ( 2 )$$

$$\text{?} \text{indicates text missing or illegible when filed}$$

Energy Discharged from Output (During 1→0 Transition at Output)

$$\int \text{?} = \text{?} = \text{?} \qquad ( 3 )$$

$$\text{?} \text{indicates text missing or illegible when filed}$$

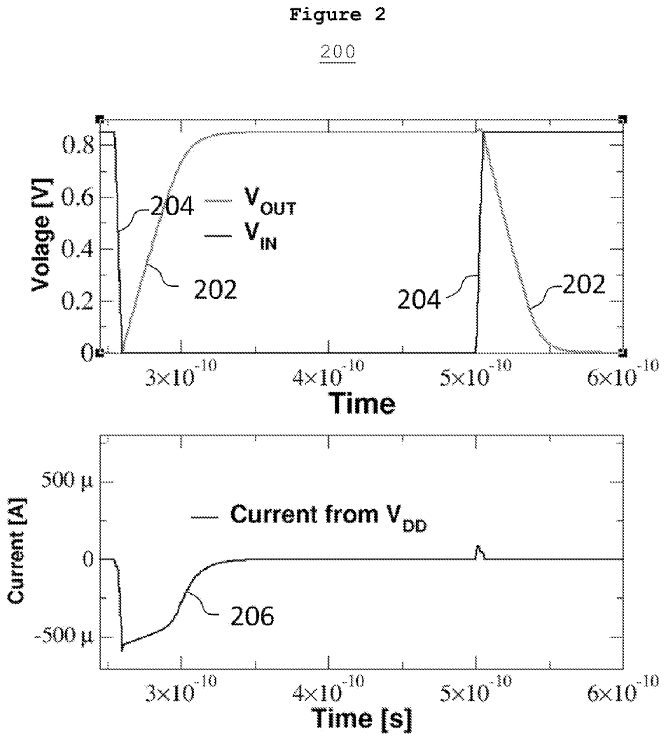

FIG. 2 200 is an illustration of the time dependent voltage waveforms of the output node OUT (102 in FIG. 1 100) shown as the waveform Vₒᵤₜ 202 in FIG. 2. The voltage waveform driving the input of the inverter 118 in FIG. 1, is shown in FIG. 2 as V_{IN} 204

The waveform of current flow 206 into the inverter from the power rail at voltage V_{DD} (106 in FIG. 1) is shown along the same x-axis of time (as used to plot voltage waveforms) in FIG. 2. The absolute value of the integral of the current waveform 206 over time in FIG. 2 200 equals the total charge Q drained from the Power rail (106 in FIG. 1) to drive the output node 102 from 0→1. The energy consumed from the power rail 106 to accomplish this logic transition at the output node 102 equals [Q·Vss]=CₒᵤₜV_{DD}² modeled in equation (1) above.

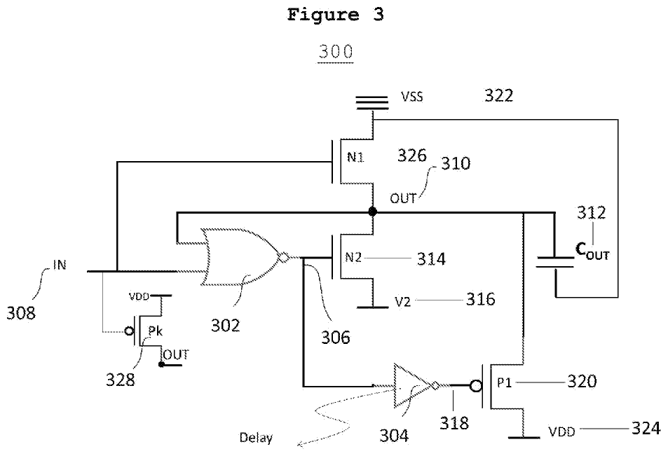

In FIG. 3 the proposed circuit schematic functioning as an inverter 300 shows: a 2-input NOR 302 and a delay element 304 that also inverts. The 2-input NOR 302 and the delay element 304 have devices with much smaller widths (˜⅕ of driver transistors) than the other transistors (326,314,320) in this schematic 300.

The NOR gate 302 in this schematic generates an active high pulse at its output node 306 whose leading edge is triggered by a 1→0 transition at the input 308 and whose trailing edge is triggered by a 0→1 transition at the output node 310 loaded with a total capacitance C_{OUT} 312.

The leading edge of this active high pulse turns on NFET N2 314 which drives charge harvested on the V2 node 316 (held at a voltage typically between VSS and VDD and preferably at a voltage comparable to the logic threshold of the NOR gate 302) to the output node 310 of this inverter.

The leading edge of the, active high pulse at the output of the NOR gate 306, when delayed and inverted to drive the gate input 318 of PFET Pl 320, turns on PFET P1 320 to begin charging the output 310 to V_{DD}—as the output voltage at node OUT 310 approaches V2. Note that a design requirement on the logic threshold voltage of the NOR gate 302 is that it is lower than the typical voltage node V2 would be raised to with harvested charge. Thus, node OUT 310 when being charged to V2 through NFET N2 314, can trip the NOR 302 to produce the high→low transition of the active high pulse at output of the NOR gate 306 to turn-off N2 314.

The NOR 302 would also trip when the P channel FET P1 320 begins conducting after the delayed and inverted leading edge of the active high pulse output from the NOR turns on P1 320.

The output terminal continues being charged to VDD by the power rail 324 as P1 320 is turned on. The trailing edge of the active low pulse driving the gate input terminal of the P channel FET 320 turns this PFET 320 off. A small geometry keeper HVT PFET 328 holds the output to V_{DD}. Its gate input is driven by the inverter input 308 with its source terminal connected to the power rail 324 at voltage V_{DD} and its drain terminal connected to OUT 310.

The trailing edge of the active high pulse at the output of the NOR 306 is triggered by the transition at the output node from 0→V2 since the logic threshold of the NOR 302 is less than the voltage at which node V2 316 is charged to with harvested charge, the trailing edge is triggered by this feedback from OUT 310 to the output of the NOR 306.

The proposed circuit (1) maintains rail-rail operation (2) drives practically the same waveforms at its output as a conventional inverter and (3) uses about 25%-40% of the total charge it drives to its output 310—from the harvest grid node V2 316, instead of getting that charge from the VDD supply rail 324. The primary overhead in area is consumed by the NFET N2 in FIG. 3. All of the other transistors in FIG. 3 are small and can be replaced by equivalent standard cells. Transistors Pl 320, NI 326 in FIG. 3 are identical to the transistors 116 and 114 in the schematic of the inverter in FIG. 1 100.

The NOR gate 302 and the delay element 304 can be optimized to maximize the energy used from the grid/node holding harvested charge according to what voltage the harvested charge is typically held at when using the proposed inverter. The closer the voltage of the harvested charge is to VDD, the higher the optimal logic threshold voltage of the NOR gate 302 is optimized at and the longer the delay value of the delay element 304 needs to be to maximize the use of harvested charge to accomplish the same 0→1 transition at the output of the inverter. This optimization is especially useful when operating at low, near threshold voltages

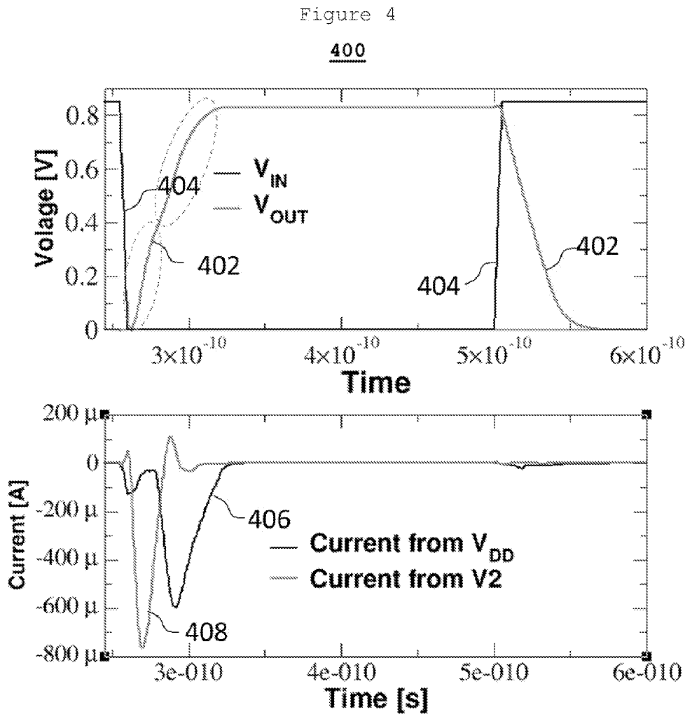

FIG. 4 400 is an illustration of the time dependent voltage waveforms Of the output node OUT (310 in FIG. 3) shown as V_{OUT} 402 in FIG. 4. The input waveform driving the input 308 of the inverter in FIG. 3, V_{IN} 404 is also shown in FIG. 4

The waveform of current flow 406 into the inverter from toe VDD power rail (324 in FIG. 3) is shown along the same x-axis (as used to plot voltage waveforms) in FIG. 4. The absolute value of the integral of Current over time in FIG. 4 400 equals the total charge Q drained from the power rail (324 in FIG. 3) to drive the output from 0→1. Note that initially the charge to drive the output in the 0→1 transition comes from the harvest charge grid/node V2 316 in FIG. 3. The total charge driven to node OUT 310 in FIG. 3 is the total area under the curves 406 and 408 in FIG. 4. This sum approximately equals the area under the current waveform 206 in FIG. 2 for the conventional CMOS inverter. Note that the voltage waveform at the output node 310 in FIG. 3 is practically the same as the voltage waveform of the output node 102 in FIG. 1 100 of a conventional inverter. However, for the schematic in FIG. 3 300 the total charge consumed from the power rail to complete the 0→1 transition at the output node 310 is only 60%-75% of the total charge taken from the power rail 106 in FIG. 1 for a conventional CMOS inverter. Total current in the comparison is based on simulation of the entire circuit shown in FIG. 1 100 and FIG. 3 300—and thus includes parasitic contributions of all transistors to circuit operation. All parasitic capacitances Of transistors in the complete schematic contribute to slew rate seen at the output and overheads incurred in propagation delay in the schematic

Switching energy Consumption by logic gates with low fanouts (<4) are typically small. Gates driving a high fanout (>10) and/or long wires consume more energy and are best candidates for the proposed scheme that uses harvested charge.

The transistor energy increases in the proposed schematic shown in FIG. 3 300 compared to the 2 transistors used in a conventional CMOS inverter. However, the area consume by the proposed schematics in FIG. 3 300 does not increase proportionally with the number of translators because the transistors of gates (302, 304 in FIG. 3) are ˜5× smaller than any of the transistors (326, 314 and 320 in FIG. 3 300). This because the load seen by the NOR gate 302 is small-essentially just the gate input, of a single NTFT (N2 314 in FIG. 3)—with the load from the delay element 304 much smaller. The transistors P1 320, N1 326 and N2 314 in FIG. 3 are comparable (in dimensions) to the transistors P1 114 and N1 116 in a conventional CMOS inverter shown in FIG. 1 100 that drives the same capacity load C_{OUT} 104 in FIGS. 1 and 312 in FIG. 3. The gate footprint of the proposed schematic 300 (in FIG. 3) is not expected to be larger than 1.7×-2.0× of the CMOS inverter it replaces. Note that the proposed schematics are preferred as replacement candidates of CMOS inverters only when driving large loads—that offer the opportunity for larger energy reductions.

Although illustrative embodiments of the present invention have been described herein, it is to be understood that the invention is not limited to those precise embodiments, and that various other changes and modification may be made by one skilled in the art without departing from-the scope of the invention.

What is claimed is:

1. (canceled)

2. An apparatus, comprising:
a power supply voltage terminal configured to provide a power supply voltage;
an input terminal;
an output terminal;
a shared capacitor terminal operatively coupled to the output terminal; and
a circuit switch associated with a delay, the circuit switch configured to, responsive to a high-to-low logic transition at the input terminal, sequentially (1) electrically couple then decouple the shared capacitor terminal and the output terminal via a first pulse and (2) electrically couple then decouple the shared capacitor terminal and the output terminal via a second pulse, the second pulse beginning after the first pulse begins and after the delay, the second pulse partially overlapping the first pulse.

3. The apparatus of claim 2, further comprising:
a NOR gate including a first input, a second input, and an output, the first input of the NOR gate being the input terminal and the second input of the NOR gate connected to the output terminal.

4. The apparatus of claim 2, further comprising:
a NOR gate including a first input, a second input, and an output, the first input of the NOR gate being the input terminal and the second input of the NOR gate connected to the output terminal; and
a first NFET including a gate terminal, a source terminal, and a drain terminal, the gate terminal of the first NFET connected to the input terminal, the source terminal of the first NFET connected to reference ground, the drain terminal of the first NFET connected to the output terminal.

5. The apparatus of claim 2, further comprising:
a NOR gate including a first input, a second input, and an output, the first input of the NOR gate being the input terminal and the second input of the NOR gate connected to the output terminal;
a first NFET including a gate terminal, a source terminal, and a drain terminal, the gate terminal of the first NFET connected to the input terminal, the source terminal of the first NFET connected to reference ground, the drain terminal of the first NFET connected to the output terminal; and
a second NFET including a gate terminal, a source terminal, and a drain terminal, the gate terminal of the second NFET connected to the output of the NOR gate, the source terminal of the second NFET connected to the output terminal, the drain terminal of the second NFET connected to the shared capacitor terminal.

6. The apparatus of claim 2, wherein
a NOR gate including a first input, a second input, and an output, the first input of the NOR gate being the input terminal and the second input of the NOR gate connected to the output terminal;
a first NFET including a gate terminal, a source terminal, and a drain terminal, the gate terminal of the first NFET connected to the input terminal, the source terminal of the first NFET connected to reference ground, the drain terminal of the first NFET connected to the output terminal;
a second NFET including a gate terminal, a source, a terminal, and a drain terminal, the gate terminal of the second NFET connected to the output of the NOR gate, the source terminal of the second NFET connected to the output terminal, the drain terminal of the second NFET connected to the shared capacitor terminal; and
following the high-to-low logic transition at the input terminal, a leading edge of an active-high pulse at the output of the NOR gate activates the second NFET during operation such that harvested charge on the shared capacitor terminal charges the output terminal raising a voltage at the output terminal above the reference ground.

7. The apparatus of claim 2, further comprising:
a NOR gate including a first input, a second input, and an output, the first input of the NOR gate being the input terminal and the second input of the NOR gate connected to the output terminal;
a first NFET including a gate terminal, a source terminal, and a drain terminal, the gate terminal of the first NFET connected to the input terminal, the source terminal of the first NFET connected to reference ground, the drain terminal of the first NFET connected to the output terminal;
a second NFET including a gate terminal, a source, a terminal, and a drain terminal, the gate terminal of the second NFET connected to the output of the NOR gate, the source terminal of the second NFET connected to the output terminal, the drain terminal of the second NFET connected to the shared capacitor terminal;
following the high-to-low logic transition at the input terminal, a leading edge of an active-high pulse at the output of the NOR gate activates the second NFET during operation such that harvested charge on at the shared capacitor terminal discharges the output terminal raising a voltage at the output terminal above the reference ground; and
a PFET including a gate terminal, a source terminal, and a drain terminal, the source terminal of the PFET being connected to the power supply voltage terminal and the drain terminal of the PFET being connected to the output terminal.

8. The apparatus of claim 2, further comprising:
a NOR gate including a first input, a second input, and an output, the first input of the NOR gate being the input terminal and the second input of the NOR gate connected to the output terminal;
a first NFET including a gate terminal, a source terminal, and a drain terminal, the gate terminal of the first NFET connected to the input terminal, the source terminal of the first NFET connected to reference ground, the drain terminal of the first NFET connected to the output terminal;
a second NFET including a gate terminal, a source, a terminal, and a drain terminal, the gate terminal of the second NFET connected to the output of the NOR gate, the source terminal of the second NFET connected to the output terminal, the drain terminal of the second NFET connected to the shared capacitor terminal;
following the high-to-low logic transition at the input terminal, a leading edge of an active-high pulse at the output of the NOR gate activates the second NFET during operation such that harvested charge on the shared capacitor terminal discharges the output terminal raising a voltage at the output terminal above the reference ground;
a PFET including a gate terminal, a source terminal, and a drain terminal, the source terminal of the PFET being connected to the power supply voltage terminal and the drain terminal of the PFET being connected to the output terminal; and
an inverter, an input of the inverter connected to the output of the NOR gate, an output of the inverter connected to the gate terminal of the PFET.

9. The apparatus of claim 8, wherein an active high pulse at the input of the inverter during operation causes the PFET to activate for a duration equal to a pulse duration of the active high pulse.

10. The apparatus of claim 8, wherein a propagation delay of the inverter during operation is substantially similar to a time for the output terminal to be charged from the reference ground to a voltage comparable to a voltage at the shared capacitor terminal.

11. The apparatus of claim 8, wherein, during operation, a pulse width of an active high pulse at the output of the NOR gate is comparable to a sum of a propagation delay of the inverter and a time for the PFET to charge the output terminal to a logic threshold voltage of the NOR gate.

12. The apparatus of claim 11, wherein, during operation:
the high-to-low logic transition at the input terminal causes the active high pulse at the output of the NOR gate,
the active high pulse at the output of the NOR gate causes the second NFET to be activated, and
the active high pulse at the output of the NOR gate, delayed by the inverter, causes the PFET to be activated

13. The apparatus of claim 2, further comprising:
a PFET including a gate terminal, a source terminal, and a drain terminal, the gate terminal of the PFET connected to the input terminal, the source terminal of the PFET connected to the power supply voltage terminal, and the drain terminal connected to the output terminal.

14. An apparatus, comprising:
a power supply voltage terminal configured to provide a power supply voltage;
a reference ground voltage terminal;
a node (1) operatively coupled to an output terminal and (2) configured to provide a node voltage;
an input terminal; and
the output terminal.

15. The apparatus of claim 14, further comprising:
a NOR gate including a first input, a second input, and an output, the first input of the NOR gate being the input terminal and the second input of the NOR gate connected to the output terminal;
a first NFET including a gate terminal, a source terminal, and a drain terminal, the gate terminal of the first NFET connected to the input terminal, the source terminal of the first NFET connected to the reference ground voltage terminal, the drain terminal of the first NFET connected to the output terminal;
a second NFET including a gate terminal, a source, terminal, and a drain terminal, the gate terminal of the second NFET connected to the output of the NOR gate, the source terminal of the second NFET connected to the output terminal, the drain terminal of the second NFET connected to the node;
a first PFET including a gate terminal, a source terminal, and a drain terminal, the source terminal of the first PFET being connected to the power supply voltage terminal and the drain terminal of the first PFET being connected to the output terminal;
an inverter, an input of the inverter connected to the output of the NOR gate, an output of the inverter connected to the gate terminal of the first PFET; and
a second PFET including a gate terminal, a source terminal, and a drain terminal, the gate terminal of the second PFET connected to the input terminal, the source terminal of the second PFET connected to the power supply voltage terminal, and the drain terminal of the second PFET connected to the output terminal.

16. The apparatus of claim 15, wherein, during operation, following a high-to-low logic transition at the input terminal, a leading edge of an active-high pulse at the output of the NOR gate activates the second NFET such that harvested charge at the node is discharged to the output terminal.

17. The apparatus of claim 15, wherein an active high pulse at the input of the inverter during operation causes the first PFET to activate for a duration equal to a pulse duration of the active high pulse.

18. The apparatus of claim 15, wherein a propagation delay of the inverter during operation is substantially comparable to a time for the output terminal to be charged from the reference ground voltage terminal to the node voltage.

19. The apparatus of claim 15, wherein, during operation:
a high-to-low logic transition at the input terminal causes an active high pulse at the output of the NOR gate,
the active high pulse at the output of the NOR gate causes the second NFET to be activated, and
the active high pulse at the output of the NOR gate causes the inverter to activate the first PFET.

20. A method, comprising:
providing a power supply voltage at a power supply voltage terminal;
providing a node voltage at a node operatively coupled to an output terminal; and
receiving, at the output terminal, a low-to-high logic transition driven by the node voltage then the power supply voltage following a high-to-low logic transition at an input terminal.

21. The method of claim 20, wherein an energy consumed to drive a low-to-high logic transition at the output terminal is partially provided by the power supply voltage terminal and partially provided by the node.
